(19) United States
(12) Patent Application Publication
(10) Pub. No.: US 2010/0006331 A1
(43) Pub. Date: Jan. 14, 2010

(54) Printed Circuit Board With Embedded Semiconductor Component and Method for Fabricating the Same

(75) Inventor: Shin-Ping Hsu, Taoyuan (TW)

Correspondence Address: EDWARDS ANGELL PALMER & DODGE LLP, P.O. BOX 55874, BOSTON, MA, 02205, US

(73) Assignee: Unimicron Technology Corporation, Taoyuan (TW)

(21) Appl. No.: 12/501,102

(22) Filed: Jul. 10, 2009

(30) Foreign Application Priority Data
Jul. 11, 2008 (TW) 097126239

(51) Int. Cl. H05K 1/16; H05K 1/11; H05K 3/30; H05K 3/10

(52) U.S. Cl. 174/260; 174/262; 29/832; 29/846

(57) ABSTRACT

A printed circuit board having a semiconductor component embedded therein and a method of fabricating the same are proposed, including: providing a circuit board body having a through hole, a first surface and an opposing second surface both provided with a core circuit layer thereon; forming on the first surface a first dielectric layer with a dielectric-layer opening for exposing part of the first surface; forming a first circuit layer on the first dielectric layer, and forming first conductive vias in the first dielectric layer; fixing in position to the through hole a semiconductor chip having an active surface with electrode pads thereon; forming in the dielectric-layer opening a third dielectric layer for covering the active surface of the semiconductor chip; forming a third circuit layer on the third dielectric layer, and forming third conductive vias in the third dielectric layer. The printed circuit board thus fabricated is warpage-free.

### BACKGROUND OF THE INVENTION

1. Field of the Invention

The present invention relates generally to semiconductor devices and methods for fabricating the same, and more particularly to a printed circuit board with an embedded semiconductor component and a method for fabricating the same.

2. Description of Related Art

Since electronic products are becoming lighter, thinner, shorter and smaller, package substrates for carrying semiconductor chips or electronic components also need to be reduced in size. Various sophisticated semiconductor packages, for example, BGA (Ball Grid Array) package technology have been developed, which is characterized in that more I/O connections can be accommodated in a unit area of a semiconductor substrate so as to meet the high integration requirement of semiconductor chips.

However, in a conventional BGA semiconductor package structure, a semiconductor chip is attached to a substrate and electrically connected to the substrate by wire bonding or flip-chip technology, and solder balls are mounted to the back side of the substrate for electrical connection. Although such a structure achieves a high pin count, long conductive wire connection paths often results in poor electrical performance when the package is applied in high-frequency application or operates at a high speed. In addition, conventional packages require multiple connection interfaces, thereby increasing the fabrication costs.

Accordingly, package substrates with embedded semiconductor chips are developed so as to shorten electrical conductive paths, decrease signal loss and distortion, and improve performance in high-speed operation.

FIG. 1 shows a semiconductor package structure disclosed by U.S. Pat. No. 6,709,898. As shown in FIG. 1, the semiconductor package structure comprises: a heat dissipating board 11 with at least a recess portion 110; a semiconductor chip 12 disposed inside the recess portion 110, wherein the semiconductor chip 12 has an active surface 12a with a plurality of electrode pads 121 and an inactive surface 12b opposite to the active surface 12a, and the inactive surface 12b of the semiconductor chip 12 is attached to the recess portion 110 through a heat conducting adhesive material 13; a build-up structure 14 is formed on the heat dissipating board 11 and the active surface 12a of the semiconductor chip 12, wherein the build-up structure 14 comprises at least a dielectric layer 141, a circuit layer 142 formed on the dielectric layer 141, and a plurality of conductive vias 143 formed in the dielectric layer 141 and electrically connected to the circuit layer 142 and the electrode pads 121, wherein the outermost circuit layer 142 of the build-up structure 14 comprises a plurality of electrical contact pads 144; and a solder mask layer 15 formed on the outermost layer of the build-up structure 14 with a plurality of openings 150 formed in the solder mask layer 15 for exposing the electrical contact pads 144.

However, the semiconductor chip 12 is attached to the bottom of the recess portion 110 through the heat conducting adhesive material 13, and thereafter the dielectric layer 141 is filled in the gap between the recess portion 110 and the semiconductor chip 12 by thermal pressing. When the dielectric layer 141 flows into the recessing portion 110, due to limitation of the size of the recess portion 110 and the surface tension of the dielectric material, the dielectric layer 141 cannot completely fill the recess portion 110, thereby forming voids.

Further, since the recess portion 110 is not completely filled with the dielectric layer 141, the surface of the dielectric layer 141 has relatively poor flatness and cannot be applied to high-level IC products. Meanwhile, when the dielectric layer 141 is filled into the recess portion 110, it may cause displacement of the semiconductor chip 12. Furthermore, due to different Coefficients of Thermal Expansion (CTE) of the heat dissipating board 11, the dielectric layer 141 and the circuit layer 142, warpage is likely to occur, thereby damaging the semiconductor chip 12 or causing difficulty in aligning the conductive vias 143 of the circuit layer 142 and the electrode pads 121 of the semiconductor chip 12, which accordingly adversely affect the electrical connection quality and product reliability.

Therefore, there exists a strong need in the art for an embedded substrate structure to overcome the drawbacks of the above-described conventional technology.

### SUMMARY OF THE INVENTION

Accordingly, an object of the present invention is to provide a printed circuit board with an embedded semiconductor component so as to improve the product yield.

Another object of the present invention is to provide a printed circuit board with an embedded semiconductor component so as to prevent warpage of the printed circuit board caused by a difference in Coefficients of Thermal Expansion (CTE) between different materials.

In order to attain the above and other objectives, the present invention provides a printed circuit board with an embedded semiconductor component, which comprises: a circuit board body having a first surface and an opposing second surface, wherein the first surface and the second surface respectively have a core circuit layer, the first surface further has a first dielectric layer with a dielectric-layer opening, the circuit body further comprises a through hole penetrating the first and second surfaces thereof and corresponding to the dielectric-layer opening, and the dielectric-layer opening is larger than the through hole; a first circuit layer formed on the first dielectric layer, a plurality of first conductive vias being formed in the first dielectric layer for electrically connecting the first circuit layer to the core circuit layer; a semiconductor chip fixed in position to the through hole of the circuit board body, wherein the semiconductor chip has an active surface with a plurality of electrode pads thereon and an inactive surface; a third dielectric layer formed in the dielectric-layer opening of the first dielectric layer and covering the active surface of the semiconductor chip; and

a third circuit layer formed on the third dielectric layer, a plurality of third conductive vias being formed in the third dielectric layer for electrically connecting the third circuit layer to the electrode pads on the semiconductor chip.

Therein, the first surface further comprises a plurality of first dielectric layers, and each of the first dielectric layers has a dielectric-layer opening larger than those of the underlying first dielectric layers.

The above-described printed circuit board further comprises a plurality of third dielectric layers and third circuit layers formed thereon, which are formed in the dielectric-layer openings of the first dielectric layers and covering the active surface of the semiconductor chip, a plurality of third conductive vias being formed in the third dielectric layers for electrically connecting the third circuit layers to the electrode pads on the semiconductor chip.

The core circuit layer on the first surface further comprises a plurality of electrically connecting pads exposed from the dielectric-layer opening of the first dielectric layer.

The printed circuit board further comprises a first build-up structure formed on the first dielectric layer(s), the third dielectric layer(s), the first circuit layer(s) and the third circuit layer(s), wherein the first build-up structure comprises a plurality of fourth conductive vias electrically connected to the first circuit layer(s) and the third circuit layer(s). The first build-up structure comprises at least a fourth dielectric layer, a fourth circuit layer formed on the fourth dielectric layer, and the plurality of fourth conductive vias formed in the fourth dielectric layer and electrically connected to the first circuit layer(s), the third circuit layer(s) and the fourth circuit layer, the outermost fourth circuit layer of the first build-up structure further comprises a plurality of first electrical contact pads, and a first solder mask layer is formed on the outermost layer of the first build-up structure with a plurality of first-solder-mask-layer openings formed for exposing the first electrical contact pads, respectively.

The printed circuit board further comprises a second solder mask layer formed on the second surface and the core circuit layer thereon, wherein a plurality of second-solder-mask-layer openings are formed in the second solder mask layer for exposing a portion of the core circuit layer so as to form a plurality of second electrical contact pads. Alternatively, the printed circuit board further comprises a second dielectric layer and a second circuit layer, wherein the second dielectric layer is formed on the second surface and the core circuit layer of the second surface, and the second circuit layer is formed on the second dielectric layer, a plurality of second conductive vias being formed in the second dielectric layer for electrically connecting the second circuit layer to the core circuit layer.

The printed circuit board further comprises a second build-up structure formed on the second dielectric layer and the second circuit layer, and a build-up structure opening is formed to penetrate the second dielectric layer and the second build-up structure, thereby exposing the inactive surface of the semiconductor chip. The second build-up structure comprises at least a fifth dielectric layer, a fifth circuit layer formed on the fifth dielectric layer, and a plurality of fifth conductive vias formed in the fifth dielectric layer and electrically connected to the second circuit layer and the fifth circuit layer, the outermost fifth circuit layer of the second build-up structure further comprises a plurality of second electrical contact pads, and a second solder mask layer is formed on the outermost layer of the second build-up structure with a plurality of second-solder-mask-layer openings formed for exposing the second electrical contact pads, respectively.

The present invention further provides a method for fabricating a printed circuit board with an embedded semiconductor component, which comprises: providing a circuit board body having a first surface and an opposing second surface, wherein the first surface and the second surface respectively have a core circuit layer; forming at least a first dielectric layer on the first surface of the circuit board body, and forming a dielectric-layer opening in the first dielectric layer so as to expose a portion of the first surface; forming a first circuit layer on the first dielectric layer, and forming a plurality of first conductive vias in the first dielectric layer for electrically connecting the first circuit layer to the core circuit layer; forming a through hole in the dielectric-layer opening, penetrating the first and second surfaces of the circuit board body, wherein the dielectric-layer opening is larger than the through hole; fixing a semiconductor chip in position to the through hole, wherein the semiconductor chip has an active surface with a plurality of electrode pads thereon and an inactive surface; forming a third dielectric layer in the dielectric-layer opening of the first dielectric layer, the third dielectric layer covering the active surface of the semiconductor chip; and forming a third circuit layer on the third dielectric layer, and forming a plurality of third conductive vias in the third dielectric layer for electrically connecting the third circuit layer to the electrode pads on the semiconductor chip.

Therein, a plurality of first dielectric layers is formed on the first surface, and each of the first dielectric layers has a dielectric-layer opening larger than those of the underlying first dielectric layers.

The above-described method further comprises forming a plurality of third dielectric layers and third circuit layers in the dielectric-layer openings of the first dielectric layers and covering the active surface of the semiconductor chip, wherein the third circuit layers are formed on the third dielectric layers and a plurality of third conductive vias is formed in the third dielectric layers for electrically connecting the third circuit layers to the electrode pads on the semiconductor chip.

The core circuit layer of the first surface further comprises a plurality of electrically connecting pads exposed from the dielectric-layer opening(s) of the first dielectric layer(s).

The above-described method further comprises forming a first build-up structure on the first dielectric layer, the third dielectric layer, the first circuit layer and the third circuit layer, wherein the first build-up structure comprises a plurality of fourth conductive vias electrically connected to the first circuit layer and the third circuit layer. The first build-up structure comprises at least a fourth dielectric layer, a fourth circuit layer formed on the fourth dielectric layer, and the plurality of fourth conductive vias formed in the fourth dielectric layer and electrically connected to the first circuit layer, the third circuit layer and the fourth circuit layer, the outermost fourth circuit layer of the first build-up structure further comprises a plurality of first electrical contact pads, and a first solder mask layer is formed on the outermost layer of the first build-up structure with a plurality of first-solder-mask-layer openings formed for exposing the first electrical contact pads, respectively.

The above-described method further comprises forming a second solder mask layer on the second surface and the core circuit layer of the second surface, wherein the second solder mask layer has a plurality of second-solder-mask-layer openings formed for exposing a portion of the core circuit layer so as to form a plurality of second electrically connecting pads. Alternatively, the method further comprises forming a second dielectric layer on the second surface and the core circuit layer of the second surface, forming a second circuit layer on the second dielectric layer, and forming a plurality of second conductive vias in the second dielectric layer for electrically connecting the second circuit layer to the core circuit layer.

The method further comprises forming a second build-up structure on the second dielectric layer and the second circuit layer, and forming a build-up structure opening to penetrate the second dielectric layer and the second build-up structure, thereby exposing the inactive surface of the semiconductor chip. The second build-up structure comprises at least a fifth dielectric layer, a fifth circuit layer formed on the fifth dielectric layer, and a plurality of fifth conductive vias formed in the fifth dielectric layer and electrically connected to the second circuit layer and the fifth circuit layer, the outermost fifth circuit layer of the second build-up structure further comprises a plurality of second electrical contact pads, and a second solder mask layer is formed on the outermost layer of the second build-up structure with a plurality of second-solder-mask-layer openings formed for exposing the second electrical contact pads, respectively.

Therefore, the present invention essentially comprises forming at least a first dielectric layer and a first circuit layer on a first surface of a circuit board body, and forming a dielectric-layer opening in the first dielectric layer; subsequently, forming a through hole in the dielectric-layer opening with the through hole penetrating the first and second surfaces of the circuit board body, wherein the dielectric-layer opening is larger than the through hole; and, fixing, upon determination that the circuit board body with the circuit layer thereon is a conforming product, a semiconductor chip in position to the through hole so as to increase the product yield. Meanwhile, a third dielectric layer can be formed in the dielectric-layer opening of the first dielectric layer so as to avoid the formation of voids in the through hole. Further, since the circuit board body is pre-prepared, instead of covering the whole surface of the circuit board body, the third dielectric layer only needs to be filled in the dielectric-layer opening of the first dielectric layer for forming a third circuit layer. Thus, during a circuit build-up process, stresses induced by the differences in CTE between the chip, the circuit board body, the dielectric layer and the circuit layer can be reduced so as to prevent warpage of the printed circuit board.

### BRIEF DESCRIPTION OF DRAWINGS

FIG. 1 shows a conventional package structure integrated with a semiconductor chip;

FIGS. 2A to 2I are sectional diagrams showing a printed circuit board with an embedded semiconductor component therein and a method for fabricating the same according to a first embodiment of the present invention;

FIG. 2E′ is a sectional diagram showing a variant embodiment as opposed to the first embodiment shown in FIG. 2E;

FIGS. 3A to 3I are sectional diagrams showing a printed circuit board with an embedded semiconductor component therein and a method for fabricating the same according to a second embodiment of the present invention; and

FIGS. 4A to 4E are sectional diagrams showing a printed circuit board with an embedded semiconductor component and a method for fabricating the same according to a third embodiment of the present invention.

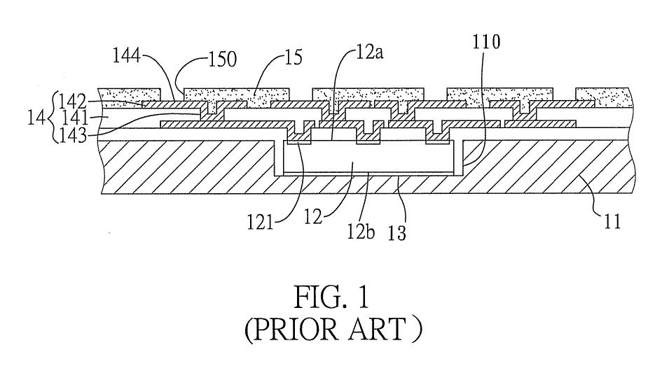

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification.

### First Embodiment

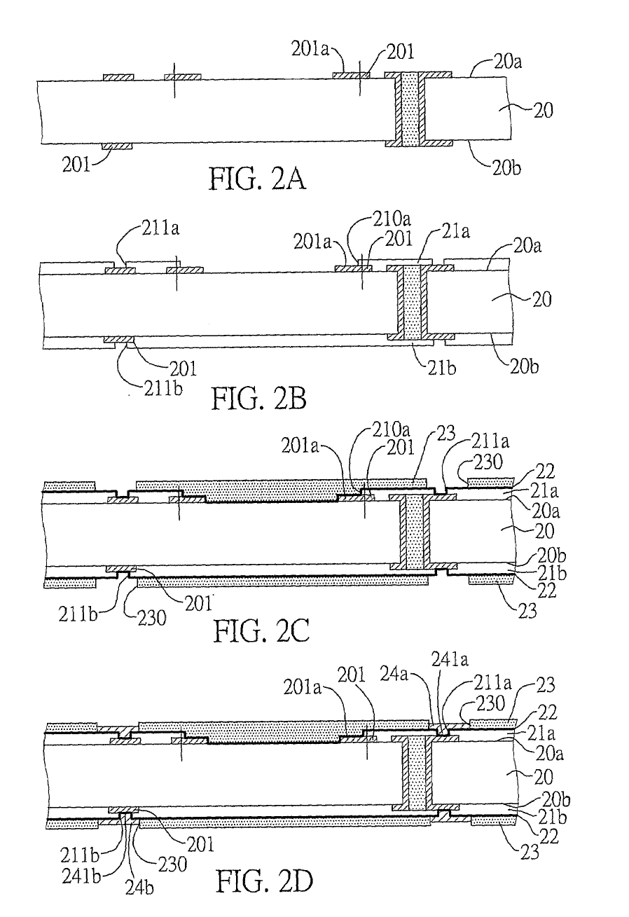

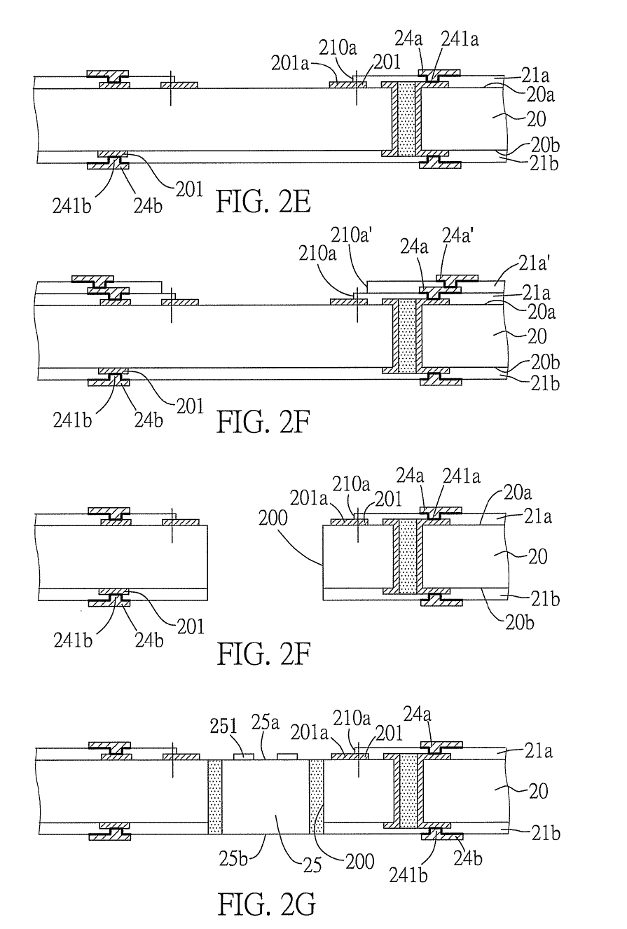

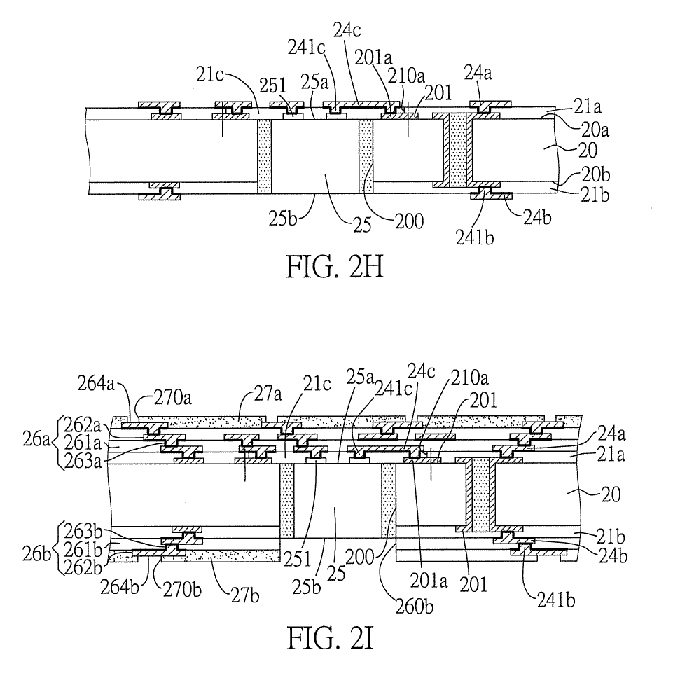

FIGS. 2A to 2I are sectional diagrams showing a method for fabricating a printed circuit board with an embedded semiconductor component according to a first embodiment of the present invention.

As shown in FIG. 2A, a circuit board body 20 is provided, which has a first surface 20a and a second surface 20b opposite to the first surface 20a. A core circuit layer 201 having a plurality of electrically connecting pads 201a is formed on the first surface 20a and the second surface 20b, respectively.

As shown in FIG. 2B, a first dielectric layer 21a and a second dielectric layer 21b are formed on the first surface 20a and the second surface 20b, respectively. A dielectric-layer opening 210a is formed in the first dielectric layer so as to expose a portion of the first surface 20a, and a plurality of first openings 211a and second openings 211b are formed in the first dielectric layer 21a and the second dielectric layer 21b, respectively, to expose a portion of the core circuit layer 201.

As shown in FIG. 2C, a conductive layer 22 is formed on the first dielectric layer 21a, the wall of the dielectric-layer opening 210a, the walls of the first openings 211a, the portion of the circuit board body 20 exposed from the dielectric-layer opening 210a, the second dielectric layer 21b and the walls of the second openings 211b. Subsequently, a resist layer 23 is formed on the conductive layer 22 and a plurality of openings 230 are formed in the resist layer 23. Portions of the openings 230 correspond in position to the first openings 211a and the second openings 211b.

As shown in FIG. 2D, a first circuit layer 24a and a second circuit layer 24b are formed in the openings 230, and a plurality of first conductive vias 241a and second conductive vias 241b are formed in the first openings 211a and the second openings 211b, respectively, for electrically connecting the first and second circuit layers to the core circuit layer 201.

As shown in FIGS. 2E and 2E′, the resist layer 23 and the conductive layer 22 covered by the resist layer 23 are removed to expose the first dielectric layer 21a, the dielectric-layer opening 210a of the first dielectric layer 21a, the first circuit layer 24a, the second dielectric layer 21b and the second circuit layer 24b. The dielectric-layer opening 210a also exposes the electrically connecting pads 201a of the core circuit layer 201, as shown in FIG. 2E. Alternatively, as shown in FIG. 2E′, which is a sectional diagram showing a variant embodiment as opposed to the first embodiment shown in FIG. 2E, a plurality of first dielectric layers 21a, 21a′ are formed on the first surface 20a, and a plurality of first circuit layers 24a, 24a′ are formed on the first dielectric layers 21a, 21a′, respectively. The outer first dielectric layers 21a′ has a dielectric-layer opening 210a′ larger than the dielectric-layer opening 210a of the inner first dielectric layer 21a. The structure shown in FIG. 2E is intended for description of subsequent processes.

As shown in FIG. 2F, a through hole 200 is formed in the dielectric-layer opening 210a to penetrate the first surface 20a, the second surface 20b and the second dielectric layer 21b. The dielectric-layer opening 210a is larger than the through hole 200.

As shown in FIG. 2G, upon determination that the circuit board body 20 with the circuit layers thereon is a conforming product, a semiconductor chip 25 is fixed in position to the through hole 200, thereby improving the product yield. Meanwhile, the semiconductor chip 25 is fixed in position to the through hole 200 so as to prevent displacement of the semiconductor chip 25 in subsequent processes. The semiconductor chip 25 has an active surface 25a with a plurality of electrode pads 251 thereon and an inactive surface 25b.

As shown in FIG. 2H, a third dielectric layer 21c is filled in the dielectric-layer opening 210a, covering the active surface 25a of the semiconductor chip 25. Meanwhile, the surface of the third dielectric layer 21c is flush with the surface of the first dielectric layer 21a. Subsequently, a third circuit layer 24c is formed on the third dielectric layer 21c, and a plurality of third conductive vias 241c are formed in the third dielectric layer 21c for electrically connecting the third circuit layer 24c to the electrode pads 251 of the semiconductor chip 25.

The semiconductor chip 25 is fixed in position to the through hole 200, and the first dielectric layer 21a has the dielectric-layer opening 210a such that the third dielectric layer 21c can be filled in the dielectric-layer opening 210a, thereby preventing the formation of voids in the through hole 200 and accordingly preventing delamination of the printed circuit board in a subsequent thermal cycling process.

As shown in FIG. 2I, a first build-up structure 26a is formed on the first dielectric layer 21a, the third dielectric layer 21c, the first circuit layer 24a and the third circuit layer 24c. The first build-up structure 26a comprises at least a fourth dielectric layer 261a, a fourth circuit layer 262a formed on the fourth dielectric layer 261a, and a plurality of fourth conductive vias 263a formed in the fourth dielectric layer 261a and electrically connected to the first circuit layer 24a, the third circuit layer 24c and the fourth circuit layer 262a. The outermost fourth circuit layer 262a has a plurality of first electrical contact pads 264a. A first solder mask layer 27a is formed on the outermost layer of the first build-up structure 26a. A plurality of first-solder-mask-layer openings 270a are formed in the first solder mask layer 27a to expose the first electrical contact pads 264a.

Further, a second build-up structure 26b is formed on the second dielectric layer 21b and the second circuit layer 24b. A build-up structure opening 260b is formed to penetrate the second dielectric layer 21b and the second build-up structure 26b, thereby exposing the inactive surface 25b of the semiconductor chip 25. The second build-up structure 26b comprises at least a fifth dielectric layer 261b, a fifth circuit layer 262b formed on the fifth dielectric layer 261b, and a plurality of fifth conductive vias 263b formed in the fifth dielectric layer 261b and electrically connected to the second circuit layer 24b and the fifth circuit layer 262b. The outermost fifth circuit layer 262b of the second build-up structure 26b has a plurality of second electrical contact pads 264b. A second solder mask layer 27b is formed on the outermost layer of the second build-up structure 26b. A plurality of second-solder-mask-layer openings 270b are formed in the second solder mask layer 27b to expose the second electrical contact pads 264b.

### Second Embodiment

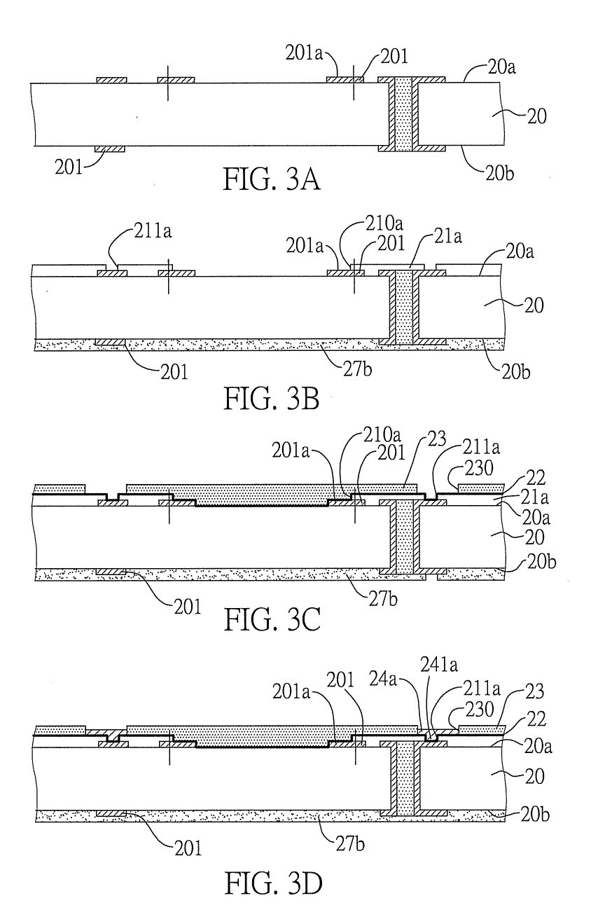

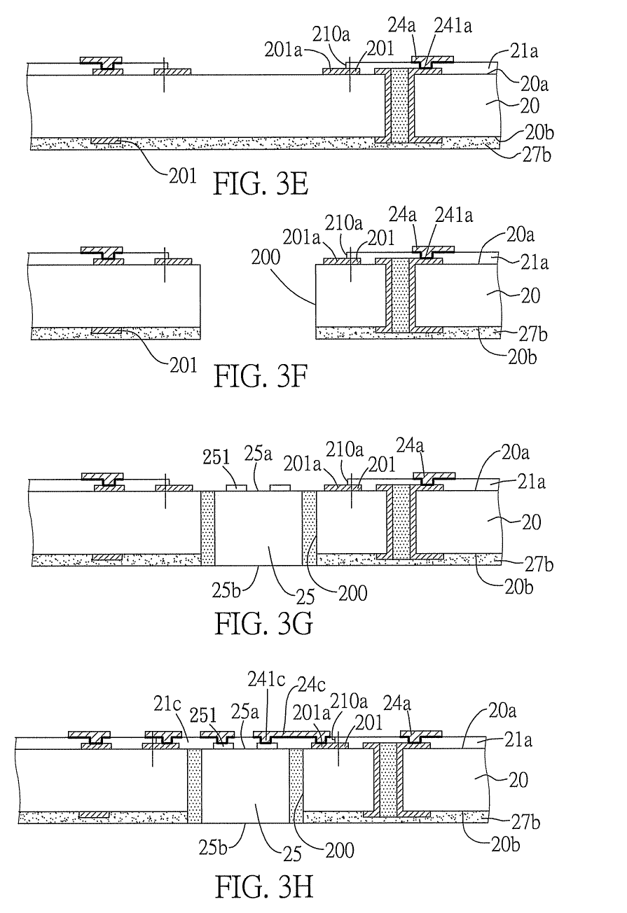

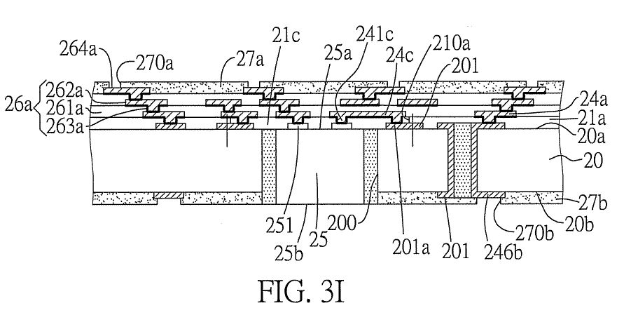

FIGS. 3A to 3I are sectional diagrams showing a method for fabricating a printed circuit board with an embedded semiconductor component according to a second embodiment of the present invention. Unlike what is proposed in the first embodiment, the second solder mask layer of the second embodiment is formed on the second surface of the circuit board body.

As shown in FIG. 3A, a structure as shown in FIG. 2A is provided.

As shown in FIG. 3B, a first dielectric layer 21a and a second solder mask layer 27b are respectively formed on the first surface 20a and the second surface 20b. A dielectric-layer opening 210a is formed in the first dielectric layer 21a so as to expose a portion of the first surface 20a, and a plurality of first openings 211a are formed in the first dielectric layer 21a to expose a portion of the core circuit layer 201.

As shown in FIG. 3C, a conductive layer 22 is formed on the first dielectric layer 21a, the wall of the dielectric-layer opening 210a, the walls of the first openings 211a and the portion of the circuit board body 20 exposed from the dielectric-layer opening 210a. Subsequently, a resist layer 23 is formed on the conductive layer 22, and a plurality of openings 230 are formed in the resist layer 23 in such a way that portions of the openings 230 correspond in position to the first openings 211a.

As shown in FIG. 3D, a first circuit layer 24a is formed in the openings 230, and a plurality of first conductive vias 241a are formed in the first openings 211a for electrically connecting the first circuit layer 24a to the core circuit layer 201.

As shown in FIG. 3E, the resist layer 23 and the conductive layer 22 covered by the resist layer 23 are removed to expose the first dielectric layer 21a, the dielectric-layer opening 210a and the first circuit layer 24a. The dielectric-layer opening 210a also exposes the electrically connecting pads 201a of the core circuit layer 201.

As shown in FIG. 3F, a through hole 200 is formed in the dielectric-layer opening 210a, penetrating the first surface 20a, the second surface 20b and the second solder mask layer 27b, wherein the dielectric-layer opening 210a is larger than the through hole 200.

As shown in FIG. 3G, upon determination that the circuit board body 20 with the circuit layers thereon is a conforming product, a semiconductor chip 25 is fixed in position to the through hole 200, thereby improving the product yield. Meanwhile, the semiconductor chip 25 is fixed in position to the through hole 200 so as to prevent displacement of the semiconductor chip 25 in subsequent processes. The semiconductor chip 25 has an active surface 25a with a plurality of electrode pads 251 thereon and an inactive surface 25b.

As shown in FIG. 3H, a third dielectric layer 21c is filled in the dielectric-layer opening 210a, covering the active surface 25a of the semiconductor chip 25, wherein the surface of the third dielectric layer 21c is flush with the surface of the first dielectric layer 21a. Subsequently, a third circuit layer 24c is formed on the third dielectric layer 21c, and a plurality of third conductive vias 241c are formed in the third dielectric layer 21c for electrically connecting the third circuit layer 24c to the electrode pads 251 of the semiconductor chip 25.

As shown in FIG. 3I, a first build-up structure 26a is formed on the first dielectric layer 21a, the third dielectric layer 21c, the first circuit layer 24a and the third circuit layer 24c. The first build-up structure 26a comprises at least a fourth dielectric layer 261a, a fourth circuit layer 262a formed on the fourth dielectric layer 261a, and a plurality of fourth conductive vias 263a formed in the fourth dielectric layer 261a and electrically connected to the first circuit layer 24a, the third circuit layer 24c and the fourth circuit layer 262a. The outermost fourth circuit layer 262a has a plurality of first electrical contact pads 264a. A first solder mask layer 27a is formed on the outermost layer of the first build-up structure 26a with a plurality of first-solder-mask-layer openings 270a formed for exposing the first electrical contact pads 264a. Further, a plurality of second-solder-mask-layer openings 270b are formed in the second solder mask layer 27b to expose a portion of the core circuit layer 201 so as to form a plurality of second electrical contact pads 264b.

The present invention further provides a printed circuit board with an embedded semiconductor component, comprising: a circuit board body 20 having a first surface 20a and an opposing second surface 20b, wherein the first surface 20a and the second surface 20b respectively have a core circuit layer 201, a first dielectric layer 21a and a second solder mask layer 27b are respectively formed on the first surface 20a and the second surface 20b, a dielectric-layer opening 210a is formed in the first dielectric layer 21a, a through hole 200 is formed to penetrate the first surface 20a, the second surface 2ob and the second solder mask layer 27b, and the dielectric-layer opening 210a is larger than the through hole 200; a first circuit layer 24a formed on the first dielectric layer 21a, wherein a plurality of first conductive vias 241a are formed in the first dielectric layer 21a to electrically connect the first circuit layer 24a to the core circuit layer 201; a semiconductor chip 25 fixed in position to the through hole 200, wherein the semiconductor chip 25 has an active surface 25a with a plurality of electrode pads 251 thereon and an opposing inactive surface 25b; a third dielectric layer 21c formed in the dielectric-layer opening 210a and covering the active surface 25a of the semiconductor chip 25; and a third circuit layer 24c formed on the third dielectric layer 21c, wherein a plurality of third conductive vias 241c are formed in the third dielectric layer 21c to electrically connect the third circuit layer 24c to the electrode pads 251 of the semiconductor chip 25.

The core circuit layer 201 on the first surface 20a further comprises a plurality of electrically connecting pads 201a exposed from the dielectric-layer opening 210a. The above structure further comprises a first build-up structure 26a formed on the first dielectric layer 21a, the third dielectric layer 21c, the first circuit layer 24a and the third circuit layer 24c. The first build-up structure 26a comprises at least a fourth dielectric layer 261a, a fourth circuit layer 262a formed on the fourth dielectric layer 261a, and a plurality of fourth conductive vias 263a formed in the fourth dielectric layer 261a and electrically connected to the first circuit layer 24a, the third circuit layer 24c and the fourth circuit layer 262a. Further, the outermost fourth circuit layer 262a has a plurality of first electrical contact pads 264a. A first solder mask layer 27a is formed on the outermost layer of the first build-up structure 26a, and a plurality of first-solder-mask-layer openings 270a are formed in the first solder mask layer 27a so as for the first electrical contact pads 264a to be exposed from the first-solder-mask-layer openings 270a.

The above-described structure further comprises a second solder mask layer 27b formed on the second surface 20b and the core circuit layer 201 of the second surface 20b. A plurality of second-solder-mask-layer openings 270b are formed in the second solder mask layer 27b to expose a portion of the core circuit layer 201 so as to form a plurality of second electrical contact pads 264b.

Alternatively, a second dielectric layer and a second circuit layer as described in the previous embodiment can be formed on the second surface 20b and the core circuit layer 201 of the second surface 20b, and a second build-up structure and a second solder mask layer can further be formed on the second dielectric layer and the second circuit layer.

### Third Embodiment

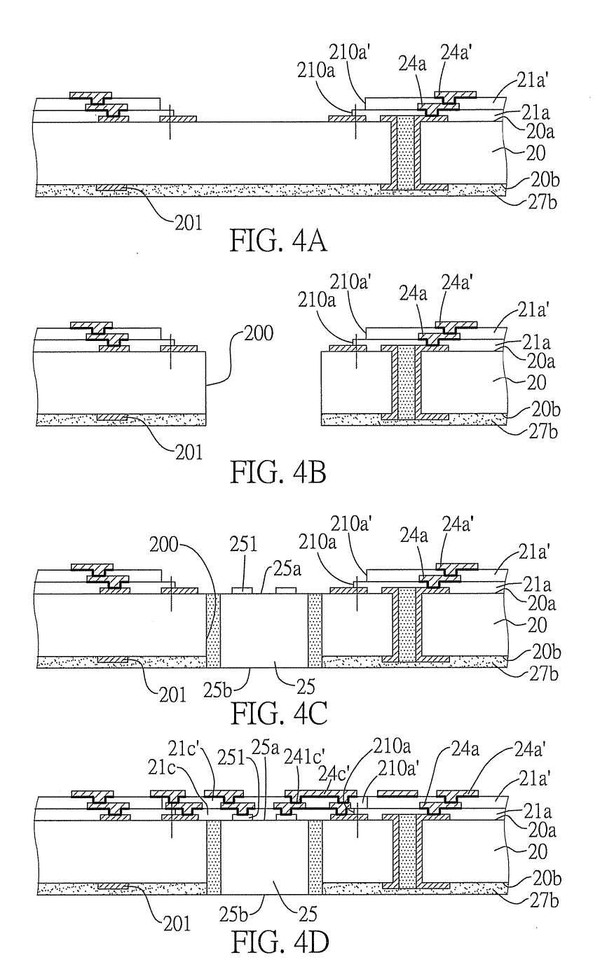

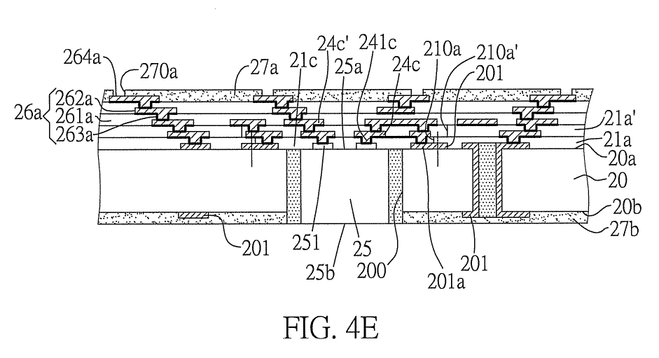

FIGS. 4A to 4D are sectional diagrams showing a method for fabricating a printed circuit board with an embedded semiconductor component according to a third embodiment of the present invention. The third embodiment is different from the previous embodiments in that, in the third embodiment, a plurality of first dielectric layers are formed on the first surface of the circuit board body, a plurality of third dielectric layers are formed in the dielectric-layer opening of the first dielectric layer, and a plurality of third circuit layers are formed on the third dielectric layers.

As shown in FIG. 4A, a structure as shown in FIG. 3E is provided, and a plurality of first dielectric layers 21a, 21a′ are formed on the first surface 20a of the circuit board body 20, wherein the dielectric-layer opening 210a′ of the outer first dielectric layer 21a′ is larger than the dielectric-layer opening 210a of the inner first dielectric layer 21a.

As shown in FIG. 4B, a through hole 200 is formed in the dielectric-layer openings 210a, 210a′, penetrating the first surface 20a, the second surface 20b and the second solder mask layer 27b, wherein the dielectric-layer openings 210a, 210a′ are larger than the through hole 200.

As shown in FIG. 4C, upon determination that the circuit board body 20 with the circuit layers thereon is a conforming product, a semiconductor chip 25 is fixed in position to the through hole 200, thereby improving the product yield. Meanwhile, the semiconductor chip 25 is fixed in position to the through hole 200 so as to prevent displacement of the semiconductor chip 25 in subsequent processes. The semiconductor chip 25 has an active surface 25a with a plurality of electrode pads 251 thereon and an inactive surface 25b.

As shown in FIG. 4D, a plurality of third dielectric layers 21c, 21c′ and third circuit layers 24c, 24c′ are formed in the dielectric-layer openings 210a, 210a′ of the first dielectric layers 21a, 21a′, wherein the third dielectric layers 21c cover the active surface 25a of the semiconductor chip 25. A plurality of third conductive vias 241c, 241c′ are formed in the third dielectric layers 21c, 21c′ for electrically connecting the electrode pads 251 of the semiconductor chip 25 and the third circuit layers 24c, 24c′.

As shown in FIG. 4E, a first build-up layer 26a is formed on the first dielectric layer 21a′, the third dielectric layer 21c′, the first circuit layer 24a′ and the third circuit layer 24c′. The first build-up structure 26a comprises at least a fourth dielectric layer 261a, a fourth circuit layer 262a formed on the fourth dielectric layer 261a, and a plurality of fourth conductive vias 263a formed in the fourth dielectric layer 261a and electrically connected to the first circuit layer 24a′, the third circuit layer 24c′ and the fourth circuit layer 262a. The outermost fourth circuit layer 262a has a plurality of first electrical contact pads 264a. A first solder mask layer 27a is formed on the outermost layer of the first build-up structure 26a, and a plurality of first-solder-mask-layer openings 270a are formed in the first solder mask layer 27a so as for the first electrical contact pads 264a to be exposed from the first-solder-mask-layer openings 270a. Furthermore, a plurality of second-solder-mask-layer openings 270b are formed in the second solder mask layer 27b to expose a portion of the core circuit layer 201 so as to form a plurality of second electrical contact pads 264b.

The present invention further provides a printed circuit board with an embedded semiconductor component, comprising: a circuit board body 20 having a first surface 20a and an opposing second surface 20b, wherein the first surface 20a and the second surface 20b respectively have a core circuit layer 201, the first surface 20a has a plurality of first dielectric layers 21a, 21a′, the second surface 20b has a second solder mask layer 27b, the first dielectric layers 21a, 21a′ respectively have dielectric-layer openings 210a, 210a′, a through hole 200 is formed to penetrate the first surface 20a, the second surface 2ob and the second solder mask layer 27b, and the dielectric-layer openings 210a, 210a′ are larger than the through hole 200; a plurality of first circuit layers 24a, 24a′ formed on the first dielectric layers 21a, 21a′, wherein a plurality of first conductive vias 241a, 241a′ are formed in the first dielectric layers 21a, 21a′ to electrically connect the core circuit layer 201 and the first circuit layers 24a, 24a′; a semiconductor chip 25 fixed in position to the through hole 200, wherein the semiconductor chip 25 has an active surface 25a with a plurality of electrode pads 251 thereon and an inactive surface 25b; a plurality of third dielectric layers 21c, 21c′ formed in the dielectric-layer openings 210a, 210a′ and covering the active surface 25a of the semiconductor chip 25; and a plurality of third circuit layers 24c, 24c′ formed on the third dielectric layers 21c, 21c′, wherein a plurality of conductive vias 241c, 241c′ are formed in the third dielectric layers 21c, 21c′ to electrically connect the electrode pads 251 and the third circuit layers 24c, 24c′.

The core circuit layer 201 on the first surface 20a further comprises a plurality of electrically connecting pads 201a exposed from the dielectric-layer opening 210a.

The above structure further comprises a first build-up structure 26a formed on the first dielectric layer 21a′, the third dielectric layer 21c′, the first circuit layer 24a′ and the third circuit layer 24c′. The first build-up structure 26a comprises at least a fourth dielectric layer 261a, a fourth circuit layer 262a formed on the fourth dielectric layer 261a, and a plurality of fourth conductive vias 263a formed in the fourth dielectric layer 261a and electrically connected to the first circuit layer 24a′, the third circuit layer 24c′ and the fourth circuit layer 262a. Further, the outermost fourth circuit layer 262a of the first build-up structure 26a has a plurality of first electrical contact pads 264a. A first solder mask layer 72a is formed on the outermost layer of the first build-up structure 26a with a plurality of first-solder-mask-layer openings 270a formed for exposing the first electrical contact pads 264a.

The above-described structure further comprises a second solder mask layer 27b formed on the second surface 20b and the core circuit layer 201 on the second surface 20b. The second solder mask layer 27b has a plurality of second-solder-mask-layer openings 270b formed for exposing a portion of the core circuit layer 201 so as to form a plurality of second electrical contact pads 264b.

Alternatively, the second dielectric layer and second circuit layer of the previous embodiment can be formed on the second surface 20b and the core circuit layer 201, and a second build-up structure and second solder mask layer can be formed on the second dielectric layer and the second circuit layer.

Therefore, the present invention mainly comprises forming at least a first dielectric layer and a first circuit layer on a first surface of a circuit board body, and forming a dielectric-layer opening in the first dielectric layer; subsequently, forming a through hole in the dielectric-layer opening with the through hole penetrating the first and second surfaces of the circuit board body, wherein the dielectric-layer opening is larger than the through hole; and further fixing a semiconductor chip in position to the through hole upon determination that the circuit board body with the circuit layer is a conforming product, thereby increasing the product yield. Meanwhile, a third dielectric layer is formed in the dielectric-layer opening of the first dielectric layer so as to avoid the formation of voids in the through hole. Further, since the circuit board body is pre-prepared, instead of covering the whole surface of the circuit board body, the third dielectric layer only needs to be filled in the dielectric-layer opening of the first dielectric layer for forming a third circuit layer. Thus, during a circuit build-up process, stresses induced by the differences in Coefficients of Thermal Expansion (CTE) between the chip, the circuit board body, the dielectric layer and the circuit layer can be reduced so as to prevent warpage of the printed circuit board. Hence, the printed circuit board is unlikely to end up with warpage which might otherwise cause damage or displacement to the semiconductor chip.

The above-described descriptions of the detailed embodiments are only to illustrate the preferred implementation according to the present invention, and it is not to limit the scope of the present invention. All modifications and variations completed by those with ordinary skill in the art should fall within the scope of present invention defined by the appended claims.

What is claimed is:

1. A printed circuit board with an embedded semiconductor component, comprising:
a circuit board body having a first surface provided with a first dielectric layer thereon, an opposing second surface, and a through hole penetrating the first and second surfaces, the first and second surfaces each having a core circuit layer, the first dielectric layer having a dielectric-layer opening formed therein and corresponding in position to the through hole, wherein the dielectric-layer opening is larger than the through hole;
a first circuit layer formed on the first dielectric layer, wherein a plurality of first conductive vias are formed in the first dielectric layer for electrically connecting the first circuit layer to the core circuit layer;
a semiconductor chip fixed in position to the through hole of the circuit board body, wherein the semiconductor chip has an active surface with a plurality of electrode pads thereon and an opposing inactive surface;
a third dielectric layer formed in the dielectric-layer opening of the first dielectric layer and covering the active surface of the semiconductor chip; and
a third circuit layer formed on the third dielectric layer, wherein a plurality of third conductive vias are formed in the third dielectric layer for electrically connecting the third circuit layer to the electrode pads on the semiconductor chip.

2. The printed circuit board of claim 1, wherein the first surface further comprises a plurality of first dielectric layers, and each of the first dielectric layers has a dielectric-layer opening larger than those of the underlying first dielectric layers.

3. The printed circuit board of claim 2, further comprising a plurality of third dielectric layers and third circuit layers provided thereon, wherein the third dielectric layers and the third circuit layers are formed in the dielectric-layer openings of the first dielectric layers and cover the active surface of the semiconductor chip, allowing a plurality of third conductive vias to be formed in the third dielectric layers for electrically connecting the third circuit layers to the electrode pads on the semiconductor chip.

4. The printed circuit board of claim 1, wherein the core circuit layer of the first surface further comprises a plurality of electrically connecting pads exposed from the dielectric-layer opening of the first dielectric layer.

5. The printed circuit board of claim 1, further comprising a first build-up structure formed on the first dielectric layer(s), the third dielectric layer(s), the first circuit layer(s) and the third circuit layer(s), wherein the first build-up structure comprises a plurality of fourth conductive vias electrically connected to the first circuit layer(s) and the third circuit layer(s).

6. The printed circuit board of claim 3, further comprising a first build-up structure formed on the first dielectric layer(s), the third dielectric layer(s), the first circuit layer(s) and the third circuit layer(s), wherein the first build-up structure comprises a plurality of fourth conductive vias electrically connected to the first circuit layer(s) and the third circuit layer(s).

7. The printed circuit board of claim 5, wherein the first build-up structure comprises at least a fourth dielectric layer, a fourth circuit layer formed on the fourth dielectric layer, and the plurality of fourth conductive vias formed in the fourth dielectric layer and electrically connected to the first circuit layer(s), the third circuit layer(s) and the fourth circuit layer, and the outermost fourth circuit layer of the first build-up structure further comprises a plurality of first electrical contact pads, allowing a first solder mask layer to be formed on the outermost layer of the first build-up structure and a plurality of first-solder-mask-layer openings to be formed in the first solder mask layer for exposing the first electrical contact pads, respectively.

8. The printed circuit board of claim 1, further comprising a second solder mask layer formed on the second surface and the core circuit layer of the second surface, wherein the second solder mask layer has a plurality of second-solder-mask-layer openings formed therein for exposing a portion of the core circuit layer so as to form a plurality of second electrical contact pads.

9. The printed circuit board of claim 1, further comprising a second dielectric layer and a second circuit layer, wherein the second dielectric layer is formed on the second surface and the core circuit layer of the second surface, and the second circuit layer is formed on the second dielectric layer, a plurality of second conductive vias being formed in the second dielectric layer for electrically connecting the second circuit layer to the core circuit layer.

10. The printed circuit board of claim 3, further comprising a second dielectric layer and a second circuit layer, wherein the second dielectric layer is formed on the second surface and the core circuit layer of the second surface, and the second circuit layer is formed on the second dielectric layer, a plurality of second conductive vias being formed in the second dielectric layer for electrically connecting the second circuit layer to the core circuit layer.

11. The printed circuit board of claim 9, further comprising a second build-up structure formed on the second dielectric layer and the second circuit layer, and a build-up structure opening is formed to penetrate the second dielectric layer and the second build-up structure, thereby exposing the inactive surface of the semiconductor chip.

12. The printed circuit board of claim 11, wherein the second build-up structure comprises at least a fifth dielectric layer, a fifth circuit layer formed on the fifth dielectric layer, and a plurality of fifth conductive vias formed in the fifth dielectric layer and electrically connected to the second circuit layer and the fifth circuit layer, the outermost fifth circuit layer of the second build-up structure further comprises a plurality of second electrical contact pads, and a second solder mask layer is formed on the outermost layer of the second build-up structure with a plurality of second-solder-mask-layer openings formed for exposing the second electrical contact pads, respectively.

13. A method for fabricating a printed circuit board with an embedded semiconductor component, comprising the steps of:
providing a circuit board body having a first surface and an opposing second surface, the first and second surfaces each having a core circuit layer;
forming at least a first dielectric layer on the first surface of the circuit board body, and forming a dielectric-layer opening in the first dielectric layer so as to expose a portion of the first surface;
forming a first circuit layer on the first dielectric layer, and forming a plurality of first conductive vias in the first dielectric layer for electrically connecting the first circuit layer to the core circuit layer;
forming a through hole in the dielectric-layer opening to penetrate the first and second surfaces of the circuit board body, wherein the dielectric-layer opening is larger than the through hole;
fixing a semiconductor chip in position to the through hole, wherein the semiconductor chip has an active surface with a plurality of electrode pads thereon and an inactive surface;
forming a third dielectric layer in the dielectric-layer opening of the first dielectric layer, the third dielectric layer covering the active surface of the semiconductor chip; and
forming a third circuit layer on the third dielectric layer, and forming a plurality of third conductive vias in the third dielectric layer for electrically connecting the third circuit layer to the electrode pads on the semiconductor chip.

14. The method of claim 13, wherein a plurality of first dielectric layers are formed on the first surface, and each of the first dielectric layers has a dielectric-layer opening larger than those of the underlying first dielectric layers.

15. The method of claim 14, further comprising forming a plurality of third dielectric layers and third circuit layers in the dielectric-layer openings of the first dielectric layers and covering the active surface of the semiconductor chip, wherein the third circuit layers are formed on the third dielectric layers and a plurality of third conductive vias are formed in the third dielectric layers for electrically connecting the third circuit layers to the electrode pads on the semiconductor chip.

16. The method of claim 13, wherein the core circuit layer on the first surface further comprises a plurality of electrically connecting pads exposed from the dielectric-layer opening(s) of the first dielectric layer(s).

17. The method of claim 15, wherein the core circuit layer on the first surface further comprises a plurality of electrically connecting pads exposed from the dielectric-layer opening(s) of the first dielectric layer(s).

18. The method of claim 13, further comprising forming a first build-up structure on the first dielectric layer, the third dielectric layer, the first circuit layer and the third circuit layer and forming a plurality of fourth conductive vias in the first build-up structure for electrical connection with the first circuit layer and the third circuit layer.

19. The method of claim 18, wherein the first build-up structure comprises at least a fourth dielectric layer, a fourth circuit layer formed on the fourth dielectric layer, and the fourth conductive vias formed in the fourth dielectric layer and electrically connected to the first circuit layer, the third circuit layer and the fourth circuit layer, thereby allowing a plurality of first electrical contact pads to be formed on the outermost fourth circuit layer of the first build-up structure, a first solder mask layer to be formed on the outermost layer of the first build-up structure, and a plurality of first-solder-mask-layer openings to be formed in the first solder mask layer for exposing the first electrical contact pads, respectively.

20. The method of claim 13, further comprising forming a second solder mask layer on the second surface and the core circuit layer thereon and forming in the second solder mask layer a plurality of second-solder-mask-layer openings for exposing a portion of the core circuit layer so as to form a plurality of second electrical contact pads.

21. The method of claim 13, further comprising forming a second dielectric layer on the second surface and the core circuit layer thereon, and forming a second circuit layer on the second dielectric layer, and forming a plurality of second conductive vias in the second dielectric layer for electrically connecting the second circuit layer to the core circuit layer.

22. The method of claim 15, further comprising forming a second dielectric layer on the second surface and the core circuit layer thereon, and forming a second circuit layer on the second dielectric layer, and forming a plurality of second conductive vias in the second dielectric layer for electrically connecting the second circuit layer to the core circuit layer.

23. The method of claim 21, further comprising forming a second build-up structure on the second dielectric layer and the second circuit layer, and forming a build-up structure opening to penetrate the second dielectric layer and the second build-up structure, thereby exposing the inactive surface of the semiconductor chip.

24. The method of claim 23, wherein the second build-up structure comprises a fifth dielectric layer, a fifth circuit layer formed on the fifth dielectric layer, and a plurality of fifth conductive vias formed in the fifth dielectric layer and electrically connected to the second circuit layer and the fifth circuit layer, allowing a plurality of second electrical contact pads to be formed on the outermost fifth circuit layer of the second build-up structure, a second solder mask layer to be formed on the outermost layer of the second build-up structure, and a plurality of second-solder-mask-layer openings to be formed in the second solder mask layer for exposing the second electrical contact pads, respectively.
